(19) United States
(12) Patent Application Publication
(10) Pub. No.: US 2012/0166918 A1
(43) Pub. Date: Jun. 28, 2012

(54) Verification of Configuration Parameters

(75) Inventors: Odd Jostein Svendsli, Trondheim (NO); Arne Aas, Trondheim (NO)

(73) Assignee: ATMEL CORPORATION, San Jose, CA (US)

(21) Appl. No.: 12/976,845

(22) Filed: Dec. 22, 2010

(51) Int. Cl. H03M 13/09; G06F 11/10

(52) U.S. Cl. 714/807; 714/E11.032

(57) ABSTRACT

In a battery management system, error detection data is generated for various configuration parameters used by the battery management system. The error detection data is compared against corresponding error detection data previously generated during production or development of a battery pack or battery pack application. Based on the comparison, an appropriate action can be taken.

### TECHNICAL FIELD

This subject matter is generally related to integrated circuit design, and more particularly to battery management systems.

### BACKGROUND

Some modern portable devices (e.g., laptop computers, mobile phones, digital cameras, video cameras, media players, personal digital assistants (PDAs), game consoles) include battery packs. A particular type of battery pack includes one or more battery cells coupled to one or more integrated circuit (IC) chips. The chips typically include a controller (e.g., a microcontroller) and circuitry and provide, among other things, battery cell management and protection.

Some battery packs include a Li-ion (Lithium ion) battery cell, which is essentially a volatile chemical reaction packaged inside a cylinder or other enclosure. Potential energy is stored in each cell, and if the battery cell is exposed to conditions outside of its specification the cell can over heat, catch fire or explode. Some battery packs configured with these volatile cells include protection circuitry for detecting unsafe conditions (e.g., charge or discharge over-currents, short circuits), and for taking corrective action to prevent damage to the battery cell and/or device, and to protect the end user.

### SUMMARY

In a battery management system, error detection data is generated for various configuration parameters used by the battery management system. The error detection data is compared against corresponding error detection data previously generated during production or development of a battery pack or battery pack application. Based on the comparison, appropriate actions can be taken.

Particular implementations of the invention realize one or more of the following advantages: 1) more fault situations are discovered by detecting incorrect values stored in memory (or hardware registers), and 2) the time and power spent for checking those values is reduced.

### DESCRIPTION OF DRAWINGS

FIG. 1 is a diagram of an application including a battery pack.

FIG. 2 is a schematic diagram of a battery pack operating circuit.

FIG. 3 is a block diagram illustrating various modules of a battery management and protection system.

FIG. 4 illustrates verification of configuration parameter groups in a battery pack.

FIG. 5 is a flow diagram of an exemplary process of verifying configuration parameter groups in a battery pack.

### DETAILED DESCRIPTION

In the following description, reference is made to a one-chip battery management and protection system in which a microcontroller, non-volatile memory and other circuit components are integrated in single integrated circuit. However, the system also can be realized in a multi-chip solution. As described below, the battery management and protection system includes autonomous safety and measurement features and can be used, for example, in a Li-ion or other battery management and protection system.

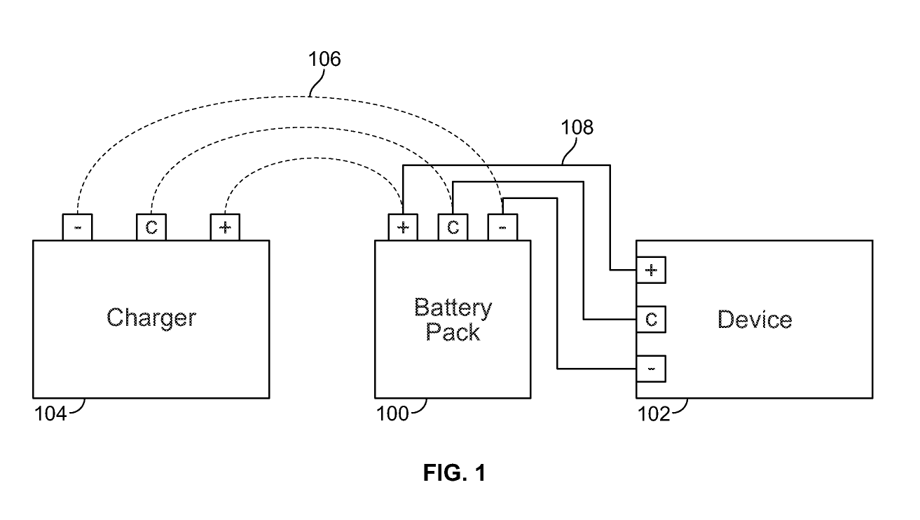

As illustrated by FIG. 1, a battery pack 100 can be coupled either to a device 102 or a charger 104 or both device 102 and charger 104. When battery pack 100 is coupled to charger 104, terminals (e.g., positive and negative terminals and a communication terminal) of battery pack 100 are coupled by a medium 106 to corresponding terminals (i.e., positive and negative and communication terminals) of charger 104 to allow for charging of cell(s) associated with battery pack 100. Medium 106 can be in the form of wires, leads, pins, or other means of electrical connection.

Similarly, when battery pack 100 is coupled to device 102, terminals (i.e., positive and negative and communication terminals) of battery pack 100 are coupled by a medium 108 to corresponding terminals (i.e., positive and negative and communication terminals) of device 102 to allow for operation of device 102. Medium 108 can be in the form of wires, leads, pins, or other means of electrical connection. In some implementations, battery pack 100 also is coupled to device 102 and charger 104 at respective communication ports, which allow for the transfer of information (e.g., command and control) between the device 102/charger 104 and battery pack 100. One example of information that can be exchanged includes the battery charge level (i.e., capacity).

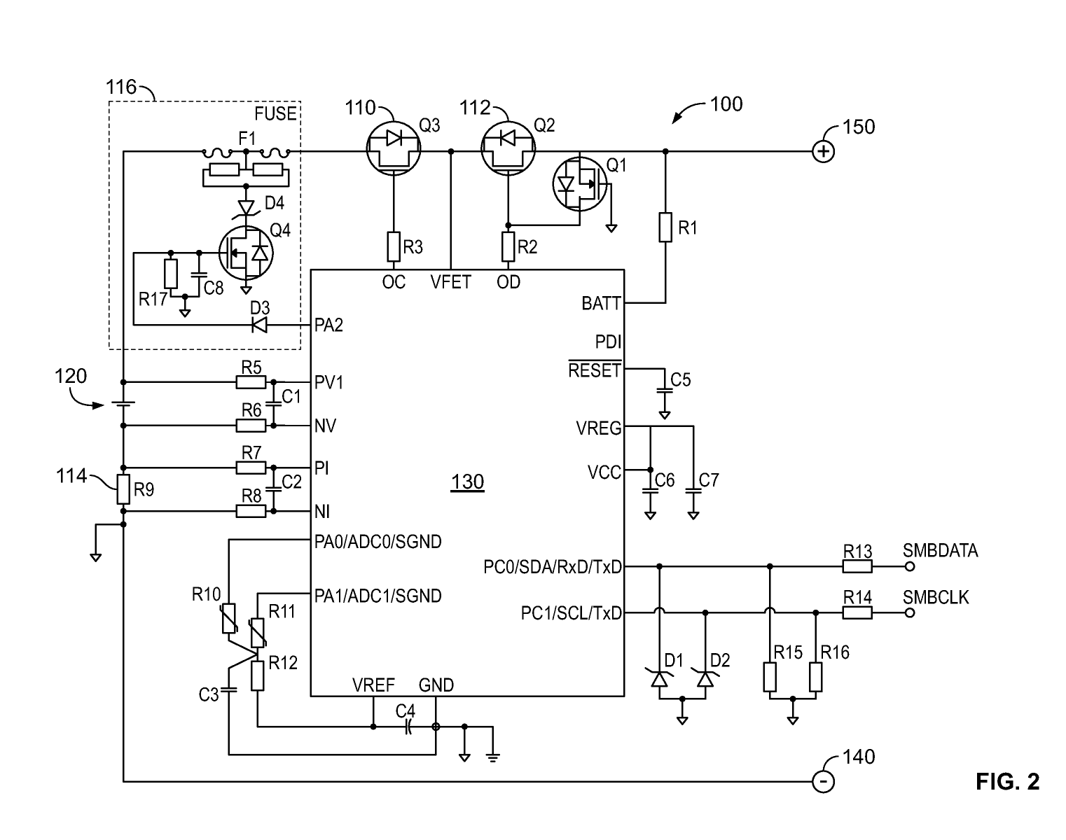

As shown in FIG. 2, battery pack 100 includes one or more battery cells 120, discrete transistors 110, 112, a sense resistor 114, and a battery management and protection system 130. System 130 includes various components, as discussed below, which can be integrated in a single package (e.g., integrated into a single integrated circuit) or packaged separately. Discrete transistors 110, 112 can be separate from system 130 and included in a separate package or can be packaged together with other system components.

Discrete transistors 110, 112 are used as switches to disconnect the battery cells 120 from the external battery pack terminals (i.e., external battery pack positive terminal 140 and negative terminal 150). In the illustrated implementation, two discrete transistors are shown, which can be implemented, for example, as field effect transistors (FETs). Although other transistor technologies can be used, FETs present advantages in terms of process, performance (e.g., on-resistance), cost and size. In the implementation shown, two transistors are provided and represent separate charge 110 and discharge 112 transistors. Charge transistor 110 is used to enable safe charging of the battery cells 120. Discharge transistor 112 is used to enable safe discharging of the battery cells 120.

As illustrated in FIG. 2, charge and discharge transistors 110, 112 are coupled in series. In some implementations, two N-channel FET (NFET) transistors are used and are coupled drain-drain in a series configuration. In other implementations, two p-channel (PFET) transistors can be used and be coupled source-source. In a PFET solution, additional diodes may be required to provide power to system 130.

In the illustrated implementation, charge and discharge transistors 110, 112 are coupled in a high-side configuration (i.e., the series transistors are coupled to the high side of the battery cell as opposed to a low-side configuration). In the high-side configuration shown, one terminal of charge transistor 110 (source) is coupled to the positive terminal of battery cell 120. One terminal of discharge transistor 112 (also source) is coupled to the external battery pack positive terminal 150. Respective second terminals of charge and discharge transistors 110, 112 are coupled to each other (forming a drain-drain junction). Gates of charge transistor 110 and discharge transistor 112 are coupled to system 130 at inputs OC and OD, respectively.

The junction between the FET transistors 110, 112 is coupled to system 130 at an input (VFET), which provides operational power to system 130. An on-chip low drop-out (LDO) voltage regulator regulates the voltage at the VFET terminal to provide a suitable supply voltage (e.g., 2.2 V) for internal logic, I/O lines and analog circuitry. This regulated voltage also is provided to external pin VREG.

Battery cell 120 is a rechargeable battery and can be of the form of lithium ion (Li-ion) or lithium polymer (Li-polymer). Other battery technology types are possible. Where multiple cells are provided, the battery cells are coupled in series, parallel or a combination of series and parallel. In the illustrated implementation, the positive terminal of battery cell 120 is coupled to system 130 (e.g., to allow for the detection of the battery voltage level at input PV1) and to one of the discrete transistors (i.e., the charge transistor 110). The negative terminal of the battery cell 120 also is coupled to system 130 to allow for the detection of the battery voltage level at input NV.

Sense resistor 114 is coupled to system 130 to allow for the measurement of current flow through sense resistor 114 at input PI. The second terminal of the sense resistor is coupled to local ground (smart battery local ground), the system 130 (to allow for the measurement of current flow through sense resistor 114 at input NI) and to the external battery pack negative terminal 140 of battery pack 100. Although a single battery cell implementation is shown, other numbers of battery cells can be included in battery pack 100. In the case of multiple cells, the terminals between the cells can be connected. For a combination of serial and parallel cells, parallel cells can be connected together and then connected in series. Therefore, only one connection to the chip is done per cell in series. In some implementations, battery pack 100 also includes circuitry 116 that serves as a fuse.

Certain battery technologies can create dangerous conditions if improperly used. For example, Li-ion and Li-polymer batteries can overheat, explode or self-ignite if they are overcharged or discharged too rapidly. Very deep discharges can also create dangerous conditions. Further, Li-ion and Li-polymer batteries can lose a significant amount of their charge capacity if they are too deeply discharged. System 130 includes supervisory electronics to help ensure fault free operation. Among other things, system 130 helps ensure that current flowing into and out of battery cell 120, as well as the voltage and temperature of battery 120, are within safe levels. Various aspects of system 130 are discussed in greater detail below.

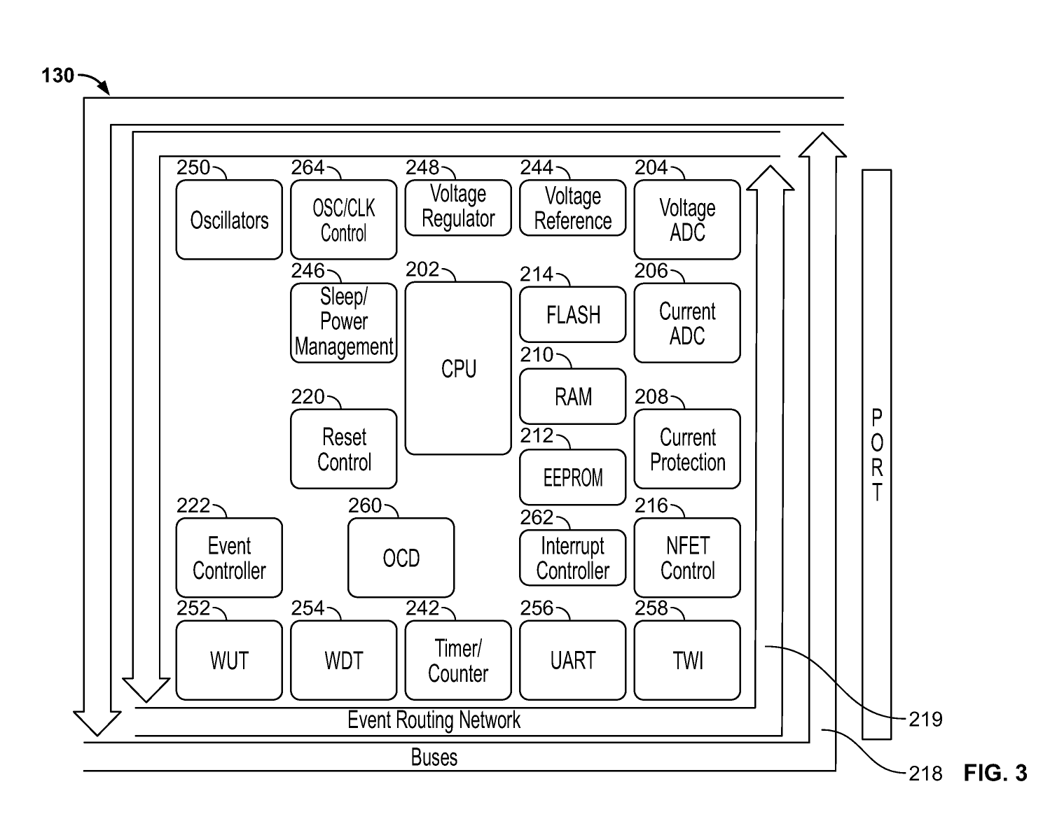

As illustrated in FIG. 3, battery management and protection system 130 includes a software-based central processing unit (CPU) 202, which can be implemented, for example, as a low-power, CMOS 8-bit microcontroller based on RISC architecture. CPU 202 ensures correct program execution and is able to access memories, perform calculations and control other modules in the system. Memory (e.g., read only memory (ROM)) stores instructions that can be executed by CPU 202. Other memory in the battery management system 130 includes random access memory (RAM) 210, EEPROM 212 and flash memory 214.

In the illustrated example, the previously-mentioned on-chip LDO regulator that regulates the VFET terminal voltage to provide a suitable supply voltage for internal logic, I/O lines and analog circuitry, can be provided as part of voltage regulator 248. The regulated voltage also is provided at pin VREG (FIG. 2).

System 130 includes various modules that perform battery measurement and provide battery protection. Such modules include a voltage analog-to-digital converter (V-ADC) module 204, a current analog-to-digital converter (C-ADC) module 206, and a current protection module 208. These modules, which include circuits and logic, are discussed in greater detail below.

V-ADC module 204 can be implemented, for example, as a 16-bit sigma-delta analog-to-digital converter that is optimized for measuring voltage and temperature. It includes several selectable input channels such as scaled battery cell voltage, general purpose inputs (e.g., for use as an external temperature sensor), an internal temperature sensor, scaled battery voltage (BATT), and diagnosis functions. V-ADC 204 can execute single conversions or channel scans controlled by firmware (i.e., controlled by CPU 202). In addition, V-ADC module 204 can execute automatic battery protection scans. In the case of a scan for the single conversion/channel scan mode, CPU 202 selects the channels and starts the scan. In contrast, automatic protection scans are performed independently of firmware (i.e., independently of CPU 202). As explained in greater detail below, the automatic protection scan is configured with auto-loaded values during start-up of system 130. V-ADC module 204 executes a channel scan and compares measured values (e.g., of battery cell voltage and/or temperature) to auto-loaded trigger levels. These features can allow V-ADC module 204 to provide accurate, but configurable protection levels for battery cell voltage and temperature.

C-ADC module 206 is arranged to measure current flowing through an external sense resistor (e.g., sense resistor 114 in FIG. 2). In the illustrated implementation, C-ADC module 206 provides both instantaneous and accumulated outputs. The instantaneous current value can be useful for various critical tasks in battery management such as supervising charging current during under-voltage recovery and fast charge, monitoring state of the battery pack (e.g., standby or discharge), providing accurate over-current protection, and performing impedance calculations. C-ADC module 206 can include a window comparator 207 to determine whether the battery current is within a user-programmable range. This feature can be used, for example, to trigger when a charger is connected or disconnected and to detect the presence of excessively high charge or discharge currents. Thus, comparator 207 can generate an interrupt signal or other event when the instantaneous current is outside the specified range for a user-programmable number of samples. In some implementations, comparator 207 is configured to generate an “event” if the current is too high and an interrupt signal if the current is low.

The illustrated system 130 includes a voltage reference module 244 that provides a highly accurate reference voltage (e.g., 1.100 V), as well as an internal temperature reference, to V-ADC module 204. The reference voltage also is provided to pin VREF (FIG. 2).

Current protection module 208 samples the voltage over sense resistor 114 at user-programmable intervals and compares the voltage against several programmable levels. The protection levels are configured by programming specific locations of the flash (or EEPROM) memory 214 with the desired protection levels. As explained in greater detail below, registers are loaded automatically from these flash memory locations during start-up of system 130. Violation counters enable time filtering of the over-current and the short-circuit current. In some implementations, current protection module 208 is configured to generate an “event” if the current is outside a specified range.

Battery management system 130 also includes a module 216 to control FET transistors 110, 112. In the illustrated implementation, FET controller 216 includes several outputs (e.g., OC, OD) coupled to external devices that can be configured by FET controller 216 to control the current flow between battery cell 120 and a device or charger. FET controller 206 includes circuits and logic for generating voltages at the outputs OC and OD. In some implementations, OC output is a high voltage output that is coupled to the gate of a charge FET (e.g., charge transistor 110) to completely or partially enable or disable the charge FET to control current flow during a charging event. OD output is a high voltage output that is coupled to the gate of a discharge FET (e.g., discharge transistor 112) to completely or partially enable or disable the discharge FET to control current flow during a discharging event.

CPU 202 and other modules send and receive signals over one or more buses 218 (FIG. 3). One such is input/output bus 218A. Another bus 218B is used for loading safety and other parameters from flash memory 214 during start-up of system 130. The system also includes an interrupt bus 218C to transfer interrupt signals from a module and the CPU. In addition, a dedicated routing network 219 allows “events” to be sent between certain modules independently of CPU.

As shown in FIG. 3, system 130 also includes a sleep/power module 246, discussed below. Other components and modules that are present in the illustrated implementation of system 130 include oscillators 250, wake-up timer 252, watchdog timer 254, universal asynchronous receiver/transmitter (UART) 256, bi-directional two-wire interface (TWI) bus 258, on-chip debug (OCD) module 260, interrupt controller 262 and oscillator/clock controller 264. A practical implementation of system 130 can include other components, modules and subsystems, which have been removed from FIG. 3 for clarity purposes. And may not include all these components.

### Autoloading of Safety and Calibration Parameters

To help improve safe operation of system 130, during system start-up various safety and calibration parameters are uploaded automatically from non-volatile memory (NVM) to dedicated input/output registers in one or more of the modules.

Safety parameters can be used by the system to determine safety functionality of battery 120. In a particular implementation, user-programmable safety parameters are stored in dedicated locations in flash memory 214. During start-up of system 130, these parameters are loaded automatically by reset controller 220 (FIG. 3) from flash memory 214 to dedicated registers 215. Bus 218B is used to transfer the safety parameters from flash memory 214 to dedicated registers 215. CPU 202 can read registers 215, but cannot write to them. Thus, safety parameters stored in dedicated registers 215 cannot be changed at run-time. By automatically loading battery protection parameters from predefined locations during the start-up cycle (e.g., a reset cycle) in a manner that is independent of CPU 202 and firmware, safe operation of system 130 can be improved.

Registers 215 can be distributed across multiple different modules that implement critical safety functions. Registers 215 in V-ADC module 204 can store, for example, information for determining the channels used in a protection scan, determining the frequency of the protection scan, and indicating the threshold levels for cell voltage comparators. Registers 215 in current protection module 208 can store, for example, information relating to current protection control, short circuit protection timing, over-current protection timing, short-circuit detection levels, discharge over-current detection levels, and charge over-current detection levels. Registers 215 in FET controller 216 can store, for example, information relating to an action to be taken when a signal indicative of one of the following events is received: a short-circuit protection event, a discharge over-current protection event, a charge over-current protection event, a cell over-voltage protection event, a cell under-voltage protection event, an internal temperature over-voltage protection event, an internal temperature under-voltage protection event. Other safety parameters also can be uploaded and stored automatically during start-up in dedicated registers 215 in these or other modules of system 130. External temperature can also be checked.

Parameters used for calibrating various aspects of system 130 also can be automatically loaded during start-up (e.g., reset) from non-volatile memory 214 to dedicated input/output registers in the same manner as described above for the safety-related parameters. Thus, for example, in some implementations, a reset request resets the device and keeps it in a reset state as long as the request is active. When all reset requests are released, system 130 goes through several stages before the internal reset is released and the system starts running. Thus, in some implementations, before the internal reset is released, a counter delay is reset and started, oscillators are started, the counter delay times out, and the safety and calibration parameters are loaded from non-volatile memory 214 as explained above. Other operations that can occur during start-up (e.g., resetting) of system 130 include setting I/O registers to their respective initial values.

### Verification of Configuration Parameters

As described above, various autonomous safety functions are controlled by safety and calibration parameters that can be configured by a customer by programming specific locations in NVM. These parameters (collectively referred to as “configuration parameters”) are automatically read by hardware and written to dedicated registers. There are also parameters that can be determined by factory test that are stored and loaded in a similar fashion.

The automatic loading can fail in several ways: 1) the values determined in the factory test or by a customer are not correctly programmed into the device; 2) the NVM memory locations are corrupted during operation; and 3) the stored values are corrupted during operation (e.g., ESD overstress, cosmic radiation).

In some implementations, firmware can check that values actually stored in the registers have values that give identical checksums to factory programmed error detection data (e.g., checksums, hash functions). This additional verification step will detect faults both in NVM and the registers, as well as other inconsistency from the factory, for example, due to production test failure or production test escapes (bad parts that are shipped due to errors). The check can be more or less assisted by hardware or performed completely in hardware, firmware or some combination of hardware and firmware.

The check can be extended to perform a check of the firmware stored in NVM or in other applications, such as a battery backed up RAM. In this case, the error detection data can be factory programmed in the NVM by the customer.

The check can be further extended to include any digital value for which error detection data can be calculated. With some modification, the check can also be extended to check analog characteristics if the device has sufficient self-test features. For example, if the device has two or more oscillators, or there is an external timing reference, the oscillator frequency ratios can be checked to determine if the ratios are within predetermined limits (due to the analog nature there should be room allowed for some variation). Voltage and temperature references can be similarly checked. Pin connections can be checked if the chip supports diagnostic features that allow detecting pin shorts or opens. Digital and memory self-tests can be checked. And any other analog parameter that can be measured can be checked.

In some implementations, there are at least two groups of parameters to be checked: parameters determined in factory production and parameters determined by a customer to adapt the chip to a particular application. Some examples of factory production parameters can include but are not limited to: voltage reference (determines the accuracy in voltage and current measurements), oscillator frequency (determines the accuracy in timings, for example setting the allowed time the current level can stay above a certain limit before it is considered risky). Some examples of customer generated parameters can include but are not limited to: maximum and minimum cell voltages, maximum current levels, maximum and minimum cell temperatures and timings for how long the measured parameters can stay above the limits before it is considered risky.

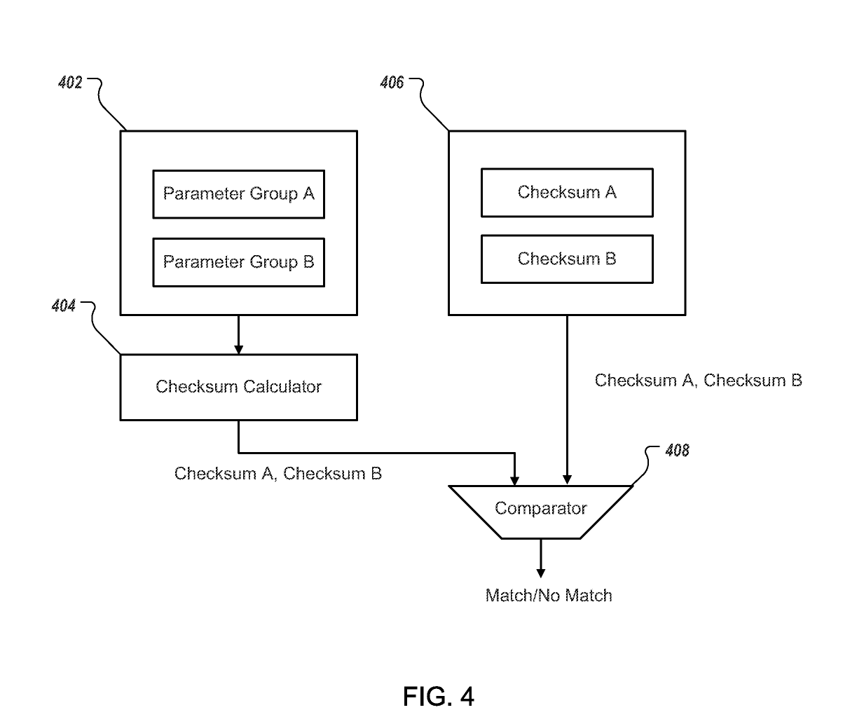

FIG. 4 illustrates verification of configuration parameter groups in a battery pack (e.g., battery pack 100). In some implementations, configuration parameters can be divided into one or more parameter groups. In this example, there are two parameter groups. Parameter group A includes parameters that are determined during factory testing and programmed into NVM 402. Parameter group B includes parameters that are determined by the customer during application development and programmed into NVM 402.

In some implementations, parameter groups A, B can be automatically loaded by hardware from NVM 402 into registers upon start-up. Other implementations may require firmware to perform the load operation. Checksum calculator 404 generates a separate checksum for parameter group A and parameter group B. For example, checksum A can be calculated for all the parameters in parameter group A and second checksum B can be calculated for all the parameters in parameter group B. A checksum is a fixed-size data computed from an arbitrary block of digital data. Checksum calculator 404 implements a checksum algorithm. Some examples of checksum algorithms can include but are not limited to: longitudinal parity check, modular sum, and position-dependent checksums. Position-dependent checksums can include Fletcher's checksum, Adler-32 and cyclic redundancy checks (CRCs). In some implementations, codes that combine error detection and error correction can be used (e.g., Reed-Solomon, Turbo codes, LDPC). Checksum calculator 404 can be dedicated hardware or performed by CPU 202 through firmware.

After checksums A and B are calculated, firmware can compare (408) checksums A and B with corresponding checksums A and B that were previously generated during production or development and stored in NVM (406). If both checksums A and B match, the configuration parameters are correct and the battery pack can proceed into normal operation. If either checksum A or checksum B does not match, then the configuration parameters are incorrect and an appropriate action can be taken by the battery pack.

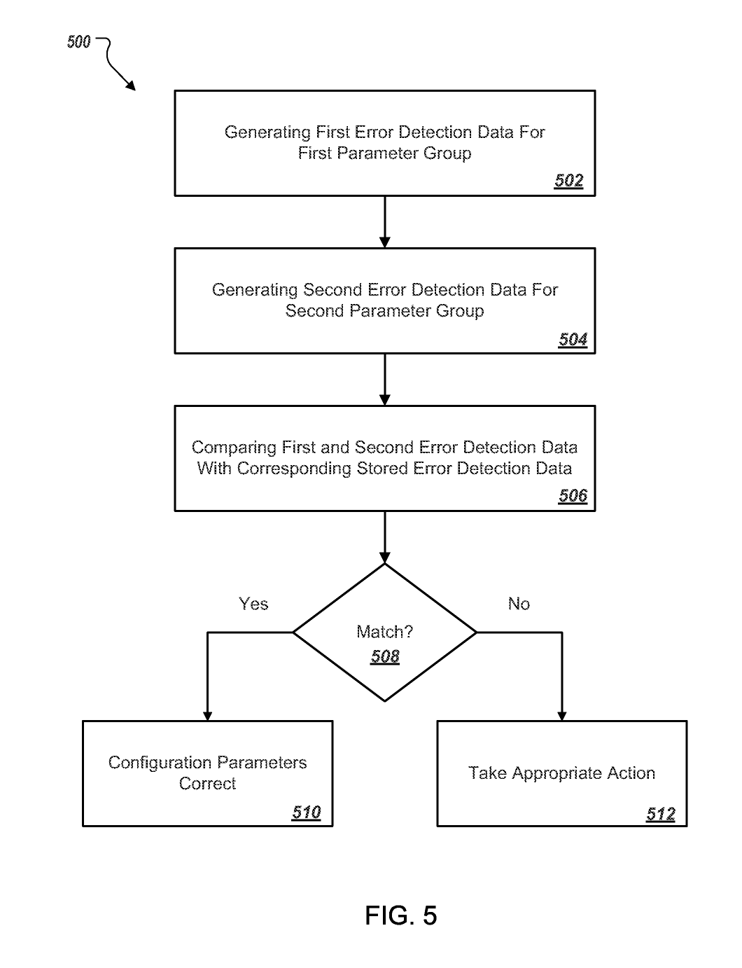

FIG. 5 is a flow diagram of an exemplary process 500 of verifying configuration parameter groups in a battery pack. Process 500 can be implemented by CPU 202 in system 132 of battery pack 100. Process 500 can be performed anytime the battery management system is woken up from an inactive state and/or regularly during operation.

Configuration parameters can be stored in NVM of battery pack 100. The parameters can be divided into a number of parameter groups. In this example, there are two parameter groups. A first parameter group includes parameters programmed into NVM during factory testing by the manufacturer, and a second parameter group includes parameters programmed into NVM during application development by a customer.

In some implementations, process 500 can begin by generating first error detection data for the first parameter group stored in NVM (502). Error detection data can be, for example, a checksum computed from a checksum algorithm (e.g., CRC). Process 500 also generates a second error detection data for the second parameter group stored in NVM (504). The error detection data can also be a checksum.

Process 500 continues by comparing the first and second error detection data with corresponding stored error detection data previously generated for the first and second parameter groups (506). If the generated error detection data for both parameter groups matches their corresponding stored error detection data (508), the configuration parameters are correct (510). If one of the error detection data does not match, the configuration parameters are incorrect, and an appropriate action be taken (512). Examples of an appropriate action can include but are not limited to: disabling external FETs to prevent battery operation, storing a notification of the failure in NVM, notifying the device 102 of the failure, initiating a system reset and/or checking the configuration parameters again.

While this document contains many specific implementation details, these should not be construed as limitations on the scope what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

What is claimed is:

1. A battery management system, comprising:
memory storing values for a group of configuration parameters; and
a processor coupled to the memory and configured to read the values from registers in the battery management system, to generate error detection data on the values, to compare the generated error detection data with corresponding previously generated error detection data for the values; and performing an action based on results of the comparison.

2. The system of claim 1, where the error detection data is a checksum.

3. The system of claim 1, where the battery management system is included in a battery pack.

4. The system of claim 1, where performing an action based on results of the comparison, further comprises:
performing at least one of disabling battery operation, storing a notification of a failure, notifying an application of the failure, initiating a reset of the system and checking the values again.

5. The system of claim 1, where the values include values for at least one of voltage reference and oscillator frequency.

6. The system of claim 1, where the values include values for at least one of maximum and minimum cell voltages, maximum current levels, maximum and minimum cell temperatures, and timings.

7. The system of claim 1, where the values include values for analog characteristics.

8. A method of verifying configuration parameters in a battery management system, comprising:
generating error detection data for a group of parameters;
comparing the error detection data with corresponding previously generated error detection data for the group of parameters; and
performing an action based on results of the comparison.

9. The method of claim 8, where the error detection data is a checksum.

10. The method of claim 8, where performing an action based on results of the comparison, further comprises:
performing at least one of disabling battery operation, storing a notification of a failure, notifying an application of the failure, initiating a reset of the system and checking the values again.

11. The method of claim 8, where the values include values for at least one of voltage reference and oscillator frequency.

12. The method of claim 8, where the values include values for at least one of maximum and minimum cell voltages, maximum current levels, maximum and minimum cell temperatures and timings.

13. The method of claim 8, where the values include values for analog characteristics.
